(19) United States
(12) Patent Application Publication
(10) Pub. No.: US 2026/0006990 A1
(43) Pub. Date: Jan. 1, 2026

(54) DISPLAY DEVICE, METHOD OF FABRICATING DISPLAY DEVICE, AND ELECTRONIC DEVICE INCLUDING THE SAME

(71) Applicant: SAMSUNG DISPLAY CO., LTD., YONGIN-SI (KR)

(72) Inventors: Jong Hwan CHA, Yongin-si (KR); Hyun Su KIM, Yongin-si (KR)

(21) Appl. No.: 19/054,129

(22) Filed: Feb. 14, 2025

(30) Foreign Application Priority Data
Jun. 26, 2024 (KR) 10-2024-0083665
Aug. 2, 2024 (KR) 10-2024-0102975

(51) Int. Cl. H10K 59/121; H10K 59/123

(52) U.S. Cl. CPC H10K 59/1213; H10K 59/123

(57) ABSTRACT

A display device includes a substrate, a bottom electrode disposed on the substrate, a subsidiary metal layer disposed on the substrate and comprising a first auxiliary metal and a second auxiliary metal, wherein the subsidiary metal layer is disposed higher than the bottom electrode relative to an upper surface of the substrate, and a transistor disposed on the subsidiary metal layer. The transistor includes an active layer comprising a source region, a channel region, and a drain region, a gate electrode disposed on the channel region of the active layer, and a source electrode and a drain electrode disposed on the gate electrode. A first vertical extension of the source electrode contacts the first auxiliary metal through a first contact hole penetrating the source region of the active layer. The drain electrode contacts the second auxiliary metal through a second contact hole penetrating the drain region of the active layer.

This application claims priority from Korean Patent Application No. 10-2024-0083665 filed on Jun. 26, 2024 and Korean Patent Application No. 10-2024-0102975 filed on Aug. 2, 2024 in the Korean Intellectual Property Office, the disclosure of each of which is incorporated herein by reference in its entirety.

### BACKGROUND

### 1. Field of the Disclosure

The present disclosure relates to a display device, and a method for fabricating the same.

### 2. Description of the Related Art

As the information-oriented society evolves, various demands for display devices are ever increasing. A display device may be a flat-panel display device such as a liquid-crystal display device, a field emission display device, and a light-emitting display device. Light-emitting display devices may include an organic light-emitting display device including organic light-emitting emitting diodes as light-emitting elements, or a light-emitting diode display device including inorganic light-emitting diodes such as light-emitting diodes (LEDs) as light-emitting elements.

A thin-film transistor can be fabricated on a glass substrate or a plastic substrate, and thus it is broadly used as a switching element of a display device such as a liquid crystal display device and an organic light-emitting display device.

Based on the material forming the active layer, thin-film transistors may be sorted into an amorphous silicon thin-film transistor in which amorphous silicon is used as the active layer, a polycrystalline silicon thin-film transistor in which polycrystalline silicon is used as the active layer, and an oxide semiconductor thin-film transistor in which an oxide semiconductor material is used as the active layer.

Among them, an oxide semiconductor thin-film transistor (oxide semiconductor TFT) has advantages in that an oxide forming the active layer can be formed at a relatively low temperature, mobility is high, and the resistance changes largely depending on the content of oxygen, so that it is easy to obtain desired physical and/or electrical properties. Since the oxide semiconductor is transparent due to the nature of oxide, it is also advantageous for implementing a transparent display.

### SUMMARY

Aspects of the present disclosure provide a display device including transistors in which an oxide semiconductor has high mobility, and a method of fabricating the same.

It should be noted that objects of the present disclosure are not limited to the above-mentioned object; and other objects of the present disclosure will be apparent to those skilled in the art from the following descriptions.

The details of one or more embodiments of the subject matter described in this specification are set forth in the accompanying drawings and the description below.

According to an aspect of the present disclosure, a display device includes a substrate, a first conductive layer disposed on the substrate and comprising a first bottom electrode and a second bottom electrode, and a transistor disposed on the first conductive layer. The transistor comprises an active layer comprising a source region, a channel region, and a drain region, a second conductive layer comprising a gate electrode disposed on the channel region of the active layer, a third conductive layer disposed on the second conductive layer and comprising a source electrode and a drain electrode, a first contact hole penetrating the source region of the active layer and exposing a first inner side surface of the source region and an upper surface of the first bottom electrode, and a second contact hole penetrating the drain region of the active layer and exposing a second inner side surface of the drain region and the second bottom electrode. The source electrode fills the first contact hole and contacts the first inner side surface of the source region and the upper surface of the first bottom electrode. The drain electrode fills the second contact hole and contacts the second inner side surface of the drain region and the upper surface of the second bottom electrode.

In some embodiments, the first bottom electrode and the second bottom electrode may be spaced apart from each other in a direction parallel to an upper surface of the substrate.

In some embodiments, the first contact hole and the second contact hole may be spaced apart from each other with the channel region of the active layer and the gate electrode therebetween.

In some embodiments, a thickness of the active layer may range from 50 angstroms to 500 angstroms.

In some embodiments, the active layer may comprise an oxide semiconductor material.

In some embodiments, the display device may further comprise a buffer layer that entirely covers the first conductive layer, wherein the first conductive layer and the active layer are spaced apart from each other with the buffer layer therebetween.

In some embodiments, the first bottom electrode and the second bottom electrode block light introduced into the active layer and stabilize electrical characteristics of the active layer.

According to an aspect of the present disclosure, a display device includes a substrate, a bottom electrode disposed on the substrate, a subsidiary metal layer disposed on the substrate and comprising a first auxiliary metal and a second auxiliary metal, wherein the subsidiary metal layer is disposed higher than the bottom electrode relative to an upper surface of the substrate, and a transistor disposed on the subsidiary metal layer. The transistor includes an active layer comprising a source region, a channel region, and a drain region, a gate electrode disposed on the channel region of the active layer, and a source electrode and a drain electrode disposed on the gate electrode. A first vertical extension of the source electrode contacts the first auxiliary metal through a first contact hole penetrating the source region of the active layer. The drain electrode contacts the second auxiliary metal through a second contact hole penetrating the drain region of the active layer.

In some embodiments, the first auxiliary metal may overlap the source region of the active layer, and the second auxiliary metal overlaps the drain region of the active layer.

In some embodiments, the first auxiliary metal and the second auxiliary metal may be spaced apart from each other in a direction parallel to the upper surface of the substrate.

In some embodiments, a thickness of the bottom electrode may range from 1,000 angstroms to 3,000 angstroms, and a thickness of the subsidiary metal layer is lower than or equal to the height of the bottom electrode.

In some embodiments, the display device may further comprise a first buffer layer that entirely covers the bottom electrode, wherein the bottom electrode and the subsidiary metal layer are spaced apart from each other with the first buffer layer therebetween.

In some embodiments, a second vertical extension of the source electrode may be in contact with the bottom electrode through a third contact hole penetrating the first buffer layer.

In some embodiments, the bottom electrode and the first auxiliary metal may be connected with each other through the source electrode.

In some embodiments, the active layer may be in contact with the first and second auxiliary metals.

In some embodiments, the first auxiliary metal may be in contact with the source region of the active layer, and the second auxiliary metal is in contact with the drain region of the active layer.

In some embodiments, the display device may further comprise a second buffer layer that entirely covers the subsidiary metal layer, and the active layer and the subsidiary metal layer are spaced apart from each other in a direction perpendicular to the upper surface of the substrate with the second buffer layer therebetween.

According to an aspect of the present disclosure, an electronic device includes a display device and a power supply providing power to the display device. The display device includes a substrate, a bottom electrode disposed on the substrate, a subsidiary metal layer disposed on the substrate and comprising a first auxiliary metal and a second auxiliary metal, wherein the subsidiary metal layer is disposed higher than the bottom electrode relative to an upper surface of the substrate, and a transistor disposed on the subsidiary metal layer. The transistor includes an active layer comprising a source region, a channel region, and a drain region, a gate electrode disposed on the channel region of the active layer, and a source electrode and a drain electrode disposed on the gate electrode. A first vertical extension of the source electrode contacts the first auxiliary metal through a first contact hole penetrating the source region of the active layer. The drain electrode contacts the second auxiliary metal through a second contact hole penetrating the drain region of the active layer.

According to an embodiment of the present disclosure, a display device can include a transistor including oxide semiconductor having high mobility.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view showing a display device according to an embodiment of the present disclosure.

FIG. 2 is a plan view showing the display panel of FIG. 1.

FIG. 3 is a circuit diagram showing a pixel according to an embodiment of the present disclosure.

FIG. 4 is a cross-sectional view of the display panel in the display area of FIG. 2.

FIG. 5 is an enlarged cross-sectional view of area A of FIG. 4.

FIG. 6 is a cross-sectional view of the display panel in the display area of FIG. 2 according to another embodiment.

FIG. 7 is an enlarged, cross-sectional view of area C of FIG. 6.

FIG. 8 is a cross-sectional view of the display panel in the display area of FIG. 2 according to yet another embodiment.

FIG. 9 is an enlarged cross-sectional view of area E of FIG. 8.

FIG. 10 is a cross-sectional view of the display panel in the display area of FIG. 2 according to yet another embodiment.

FIGS. 11 to 16 are flowcharts showing a method for fabricating a portion of the transistor layer included in the display panel of FIG. 4.

FIG. 17 is a block diagram of an electronic device according to one embodiment of the present disclosure.

FIG. 18 is a schematic diagram of an electronic device according to various embodiments of the present disclosure.

### DETAILED DESCRIPTION OF THE EMBODIMENTS

The present disclosure will now be described more fully herein with reference to the accompanying drawings, in which some embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It is also to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the disclosure. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

The present inventive concept relates to a source electrode and a drain electrode of a pixel transistor contact an active layer and a lower electrode at the same time through a contact hole penetrating the active layer. With the formation of the contact hole penetrating the active layer, a thickness range in which the active layer maintains high mobility of carriers such as electron without generating defects affecting an electrical property of the active layer due to overetching. In particular, the active layer may include an oxide semiconductor material.

Hereinafter, embodiments of the present disclosure will be described in detail with reference to the accompanying drawings.

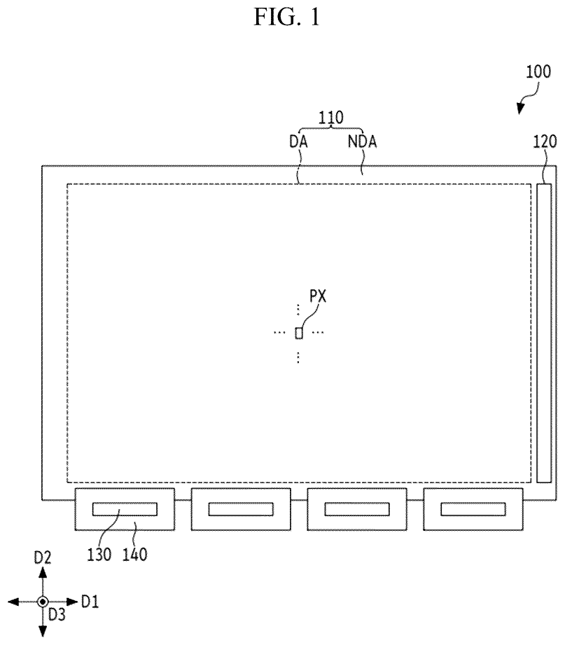

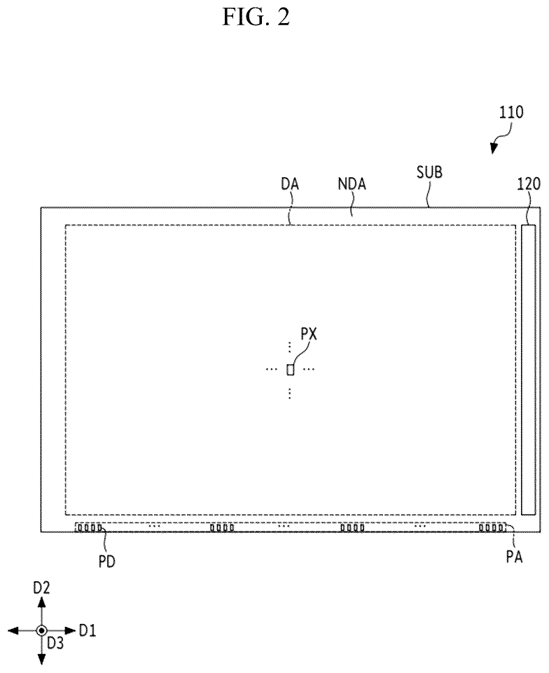

FIG. 1 is a plan view showing a display device according to an embodiment of the present disclosure. FIG. 2 is a plan view showing the display panel of FIG. 1.

Referring to FIGS. 1 to 2, a display device 100 is for displaying moving images or still images. The display device 1 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and an ultra-mobile PC (UMPC), as well as the display screen of various products such as a television, a notebook, a monitor, a billboard and the Internet of Things (IoT). These products listed-above are merely as examples, and the display device 100 may be employed in other electronic devices as well.

According to an embodiment of the present disclosure, the display device 100 may be a light-emitting display device such as an organic light-emitting display device including organic light-emitting diodes, a quantum-dot light-emitting display device including quantum-dot light-emitting layer, and an ultra-small light-emitting display device including ultra-small light-emitting diodes such as micro light-emitting diodes and nano light-emitting diodes. However, it should be understood that the present disclosure is not limited thereto. For example, the display device 100 may be other types of display devices than light-emitting display devices. In the following description, a light-emitting display device (e.g., an organic light-emitting display device) is disclosed as the display device 100.

The display device 100 may include a display panel 110 including pixels PX, and a first driver 120 and second drivers 130 that supply driving signals to the pixels PX. The display device 100 may further include additional elements. For example, the display device 100 may further include a power supply unit for supplying supply voltages to the pixels PX, the first driver 120 and the second drivers 130, and a timing controller for controlling the operation of the first driver 120 and the second drivers 130.

The display panel 110 may include a display area DA and a non-display area NDA. The display area DA may include pixels PX to display images. For example, the display area DA may include pixel areas where the pixels PX are disposed. The non-display area NDA may be an area other than the display area DA. No image is displayed in the non-display area NDA. According to the embodiment of the present disclosure, the non-display area NDA may surround the display area DA.

In FIGS. 1 and 2, a first direction D1, a second direction D2 and a third direction D3 are defined. According to the embodiment of the present disclosure, the first direction D1 may be the horizontal direction of the display panel 110, and the second direction D2 may be the vertical direction of the display panel 110. The third direction D3 may refer to the thickness direction of the display panel 110. For example, the first and second directions D1 and D2 are parallel to an upper surface of a substrate, which will be described, and the third direction D3 is perpendicular to the upper surface of the substrate.

According to the embodiment of the present disclosure, the display panel 110 may have a rectangular shape when viewed from the top. Although the display panel 110 has the horizontal length larger than the vertical length in FIGS. 1 and 2, the shape of the display panel 110 is not limited thereto. For example, the display panel 110 may have a shape in which the vertical length is larger than the horizontal length, or may have a square shape. The display panel 110 may include sharp corners or rounded corners.

The shape of the display panel 110 when viewed from the top is not limited to the above-described rectangular shapes but other shapes may be employed. For example, the display panel 110 may have a polygonal shape other than a rectangle, a circular shape, an elliptical shape, or other shapes.

According to the embodiment of the present disclosure, the display panel 110 may be substantially flat on the plane defined by the first direction D1 and the second direction D2, and may have a uniform thickness in the third direction D3. Alternatively, the display panel 110 may be implemented in a three-dimensional shape having a curved surface.

The display panel 110 may be a rigid display panel that is not substantially deformed, or a flexible display panel that can be deformed, i.e., at least partially folded, bent or rolled. The display panel 110 may be provided to the display device 100 without being bent or with being partially bent.

The display panel 110 may include a display panel 110A, a display panel 110C, a display panel 110E, and a display panel 110G. More detailed descriptions will be given below.

The display panel 110 may include a substrate SUB and pixels PX disposed on the substrate SUB. The pixels PX may be disposed in the display area DA on the substrate SUB.

The substrate SUB may be a base member for fabricating or providing the display panel 110 and may form a base surface of the display panel 110. The substrate SUB may include the display area DA and the non-display area NDA surrounding the display area DA.

The display area DA may have a variety of shapes according to embodiments. For example, the display area DA may have a rectangular shape, a non-rectangular polygonal shape, a circular shape, an elliptical shape, an irregular shape, or other shapes. According to an embodiment of the present disclosure, the display area DA may have a shape that conforms to the shape of the display panel 110.

The pixels PX may be provided and/or arranged in the display area DA. For example, the display area DA may include a number of pixel areas where the pixels PX are disposed.

According to the embodiment of the present disclosure, the display device 100 may be a light-emitting display device, and each of the pixels PX may include a light-emitting element located in the respective emission area and a pixel circuit connected to the light-emitting element. In the following description of the embodiments, the term “connection” may encompass electrical connection and/or physical connection. Each of the pixel circuits may include transistors (e.g., transistors including a driving transistor that generates a driving current corresponding to a data signal, and at least one switching transistor), and at least one capacitor (e.g., a capacitor including a storage capacitor).

The non-display area NDA may include a pad area PA where pads PD are disposed. According to an embodiment of the present disclosure, the non-display area NDA may further include a driver circuit area located on at least one side of the display area DA. At least one driver, pads PD and/or lines may be disposed in the non-display area NDA.

At least one driver for driving the pixels PX or a part of the driver may be disposed in the driver circuit area. For example, circuit elements forming the first driver 120 (e.g., driver transistors and driver capacitors forming stage circuits of the first driver 120) may be disposed in the driver circuit area on the substrate SUB. According to the embodiment of the present disclosure, the circuit elements of the first driver 120 may be formed in the display panel 110 together with the pixels PX. According to the embodiment of the present disclosure, the driver transistors provided to the first driver 120 may be transistors of substantially the same or similar type and/or structure as the transistors provided to the pixels PX, and may be formed together with transistors of the pixels PX.

The pads PD may be disposed in the pad area PA. At least one circuit board 140 may be disposed and/or bonded on the pad area PA. According to the embodiment of the present disclosure, a plurality of circuit boards 140 connected to different pads PD may be disposed on the pad area PA. The pads PD may include signal pads and power pads for transmitting the driving signals and the supply voltages to drive the pixels PX and/or the first driver 120 of the display panel 110.

The first driver 120 and the second drivers 130 may generate driving signals for controlling the operation timing and brightness of the pixels PX, and may provide the driving signals to the pixels PX. For example, the first driver 120 may be a gate driver including a scan driver, and may be connected to the pixels PX through the respective gate lines. The first driver 120 may supply gate signals (e.g., control signals that control the operation timing of the pixels PX, including scan signals and/or emission control signals) to the pixels PX. The second drivers 130 may be data drivers including source driver circuits and may be connected to the pixels PX through the respective data lines. The second drivers 130 may supply the respective data signals to the pixels PX.

According to an embodiment of the present disclosure, at least one of the first driver 120 and the second drivers 130 or a part of the at least one driver may be incorporated into the display panel 110. For example, the first driver 120 or a part of the first driver 120 may be disposed on the substrate SUB of the display panel 110 and may be disposed and/or formed in the non-display area NDA.

Although the first driver 120 is formed on one side of the display area DA (for example, in the non-display area NDA on the right side of the display area DA) in the example shown in FIG. 1, the embodiments of the present disclosure are not limited thereto. For example, the first driver 120 may be located only on the other side of the display area DA (for example, in the non-display area NDA on the left side of the display area DA), or located on the opposite sides of the display area DA (for example, in the non-display area NDA on the left and right sides of the display area DA). Alternatively, a part of the first driver 120 may be located in the non-display area NDA, while another part of the first driver 120 may be located in a non-emission area (for example, an area between the emission areas of the pixels PX) in the display area DA.

According to an embodiment of the present disclosure, the other one of the first driver 120 and the second drivers 130 or a part of the other driver may be disposed or formed outside the display panel 110 and may be electrically connected to the display panel 110. For example, the second drivers 130 may be implemented with a plurality of integrated circuit chips and may be disposed on the circuit boards 140 electrically connected to the pixels PX of the display panel 110. The second drivers 130 may be implemented as at least one integrated circuit chip and may be mounted on the non-display area NDA of the display panel 110.

The circuit boards 140 may be connected to the display panel 110 through the pads PD. According to the embodiment of the present disclosure, the circuit board 140 may be, but is not limited to, a flexible printed circuit board (FPCB), a printed circuit board (PCB) or a flexible film such as chip on film (COF). According to an embodiment of the present disclosure, the circuit boards 140 may be connected to a timing controller and/or a power supply unit through another circuit board or a connector.

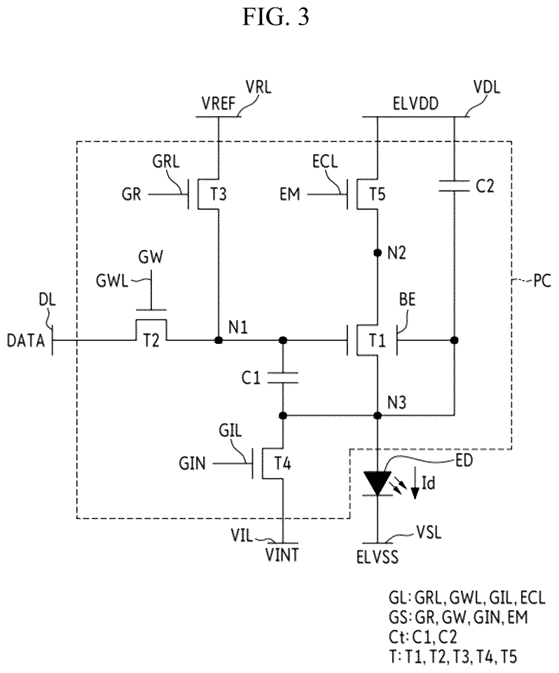

FIG. 3 is a circuit diagram showing a pixel according to an embodiment of the present disclosure. For example, FIG. 3 shows a pixel PX of a light-emitting display device including a light-emitting element ED. In addition to the embodiment of FIG. 3, the type and/or structure of the pixel PX that may be included in the display device 100 may vary depending on the embodiments.

Referring to FIG. 3 in conjunction with FIGS. 1 and 2, the pixel PX may include the light-emitting element ED and a pixel circuit PC connected to the light-emitting element ED. The light-emitting element ED is a light source of the pixel PX and may be, but is not limited to, an organic light-emitting diode. The pixel circuit PC may control the emission timing and brightness of the light-emitting element ED.

The pixel circuit PC may include transistors T and at least one capacitor Ct. For example, the pixel circuit PC may include first to fifth transistors T1 to T5, and first and second capacitors C1 and C2. Although all of the transistors T are n-type transistors according to the embodiment of FIG. 3, the types of the transistors T are not limited thereto. For example, at least one transistor T may be formed as a p-type transistor.

The pixel circuit PC may supply the driving current Id to the light-emitting element ED in response to the driving signals supplied from the first driver 120 and the second driver 130. For example, the pixel circuit PC may supply the driving current Id to the light-emitting element ED in response to the gate signals GS supplied from the first driver 120 through the respective gate lines GL and the data signal DATA supplied from the second driver 130 through the data lines DL.

The first transistor T1 may be a driving transistor of the pixel PX in which the magnitude of the drain-source current (e.g., driving current Id) is determined depending on the gate-source voltage. The second, third, fourth and fifth transistors T2, T3, T4 and T5 may be switching transistors that are turned on or off depending on the respective gate-source voltages. Depending on the type (e.g., p-type or n-type transistor) and/or operating conditions of each of the first to fifth transistors T1 to T5, the first electrode of each of the first to fifth transistors T1 to T5 may be a drain electrode (or drain region) or a source electrode (or source region) while the second electrode thereof may be an electrode different from the first electrode. For example, if the first electrode is the drain electrode, the second electrode may be the source electrode.

The pixel PX may be connected to a first gate line GWL transmitting a first gate signal GW (e.g., a scan signal), a second gate line GIL transmitting a second gate signal GIN, a third gate line GRL transmitting a third gate signal GR, an emission control line ECL transmitting an emission control signal EM, and a data line DL transmitting a data signal DATA. The pixel PX may be connected to a first voltage line VDL transmitting a first pixel voltage ELVDD (also referred to as “first pixel supply voltage”), and a second voltage line VSL transmitting a second pixel voltage ELVSS (also referred to as “second pixel supply voltage”). According to an embodiment of the present disclosure, the pixel PX may be further connected to an initialization voltage line VIL transmitting an initialization voltage VINT (also referred to as “third pixel supply voltage”), and a reference voltage line VRL transmitting a reference voltage VREF (also referred to as “fourth pixel supply voltage”).

According to an embodiment of the present disclosure, the first to fifth transistors T1 to T5 may be located in the respective pixel areas and may be oxide transistors (also referred to as “oxide semiconductor transistors”) including an oxide semiconductor (e.g., an oxide semiconductor material). For example, the active layer of each of the first to fifth transistors T1 to T5 may include an oxide semiconductor.

Oxide semiconductors have high carrier mobility and low leakage current, and accordingly, a large voltage drop may not occur even if an oxide transistor is driven for a long period of time. For example, the pixel PX including an oxide transistor can be driven at a low frequency because changes in brightness and/or color of images due to a voltage drop are ignorable even when driven at a low frequency. When the first to fifth transistors T1 to T5 are formed of oxide transistors, it is possible to suppress or prevent leakage current of the pixel PX and to save power consumption.

Oxide semiconductors are sensitive to light, and thus the amount of electric current may change due to external light. According to the embodiment of the present disclosure, a bottom electrode BE may be disposed under the active layer included in at least one transistor T to block external light. Accordingly, the operating characteristics of the transistor T can be stabilized.

The first transistor T1 may include a gate electrode connected to a first node N1, a first electrode (e.g., a drain electrode) connected to a second node N2, and a second electrode (e.g., a source electrode) connected to a third node N3. The first electrode of the first transistor T1 may be connected to the first voltage line VDL via a fifth transistor T5, and the second electrode may be connected to the light-emitting element ED. The first transistor T1 may control the magnitude (e.g., amount of current) of the driving current Id flowing to the light-emitting element ED in response to the data signal DATA transmitted to the first node N1.

According to the embodiment of the present disclosure, the first transistor T1 may further include the bottom electrode BE connected to the third node N3. For example, the bottom electrode BE may be connected to the third node N3 so that the first transistor T1 is implemented as a transistor with a double-gate structure (e.g., a double-gate transistor with a source-sync structure), thereby improving the operating characteristics of the first transistor T1.

The second transistor T2 may include a gate electrode connected to the first gate line GWL, a first electrode connected to the data line DL, and a second electrode connected to the first node N1. The second transistor T2 may be turned on by the first gate signal GW (e.g., the first gate signal GW of a gate-on voltage) transmitted to the first gate line GWL to connect the data line DL with the first node N1. Accordingly, the data signal DATA transmitted on the data line DL may be transmitted to the first node N1.

The third transistor T3 may include a gate electrode connected to the third gate line GRL, a first electrode connected to the reference voltage line VRL, and a second electrode connected to the first node N1. The third transistor T3 may be turned on by the third gate signal GR transmitted to the third gate line GRL and may transmit the reference voltage VREF transmitted to the reference voltage line VRL to the first node N1.

The fourth transistor T4 may include a gate electrode connected to the second gate line GIL, a first electrode connected to the third node N3, and a second electrode connected to the initialization voltage line VIL. The fourth transistor T4 may be turned on by the second gate signal GIN transmitted on the second gate line GIL, and may transmit the initialization voltage VINT transmitted on the initialization voltage line VIL to the third node N3.

The fifth transistor T5 may include a gate electrode connected to the emission control line ECL, a first electrode connected to the first voltage line VDL, and a second electrode (or the first electrode of the first transistor T1) connected to the second node. The fifth transistor T5 may be turned on by the emission control signal EM (e.g., the emission control signal EM of the gate-on voltage) transmitted on the emission control line ECL to control the timing of emission of the pixel PX.

Each of the second to fifth transistors T2 to T5 may or may not include a bottom electrode. According to an embodiment of the present disclosure, at least one switching transistor among the second to fifth transistors T2 to T5 may include a bottom electrode, and the bottom electrode of the at least one switching transistor may be connected to the gate electrode of the switching transistor. By connecting the bottom electrode of a switching transistor to the gate electrode thereof, the off characteristics and switching speed of the switching transistor can be improved, an additional voltage tolerance range can be obtained, leakage current can be reduced, and voltage stability can be improved. For example, the operating characteristics of the switching transistor, which is formed of an oxide transistor with a short channel length, can be improved by forming it into a double-gate structure such as a gate-sync architecture.

A first capacitor C1 may be connected between the first node N1 and the third node N3. The first capacitor C1 may be a storage capacitor of the pixel PX and may store a threshold voltage of the first transistor T1 and a voltage corresponding to a data signal DATA (e.g., data voltage). In an embodiment, the first capacitor C1 (i.e., a storage capacitor) may hold the voltage (or charges) applied to the gate of the first transistor T1 (i.e., the driving transistor). The stored charges ensure that the first transistor T1 continues to operate in the desired state (e.g., driving a pixel) even when the control signal of the first transistor T1 is no longer actively being applied. More specifically, the voltage applied to the gate of the first transistor T1 may maintain its state during a refresh period in a display system, thereby producing pixel luminance until the next refresh cycle.

A second capacitor C2 may be connected between the first voltage line VDL and the third node N3. According to an embodiment of the present disclosure, the capacitance of the second capacitor C2 may be smaller than the capacitance of the first capacitor C1.

The light-emitting element ED may be connected between the third node N3 and the second voltage line VSL. For example, the light-emitting element ED may include a first electrode (e.g., anode electrode) connected to the third node N3, a second electrode (e.g., cathode electrode) facing the first electrode and connected to the second voltage line VSL, and an emissive layer interposed between the first electrode and the second electrode. According to an embodiment of the present disclosure, the first electrode of the light-emitting element ED may be an individual electrode disposed separately in each of the pixels PX, while the second electrode of the light-emitting element ED may be a common electrode shared by a plurality of pixels PX. The light-emitting element ED may emit light with a brightness in proportional to the driving current Id while the driving current Id is supplied from the pixel circuit PC.

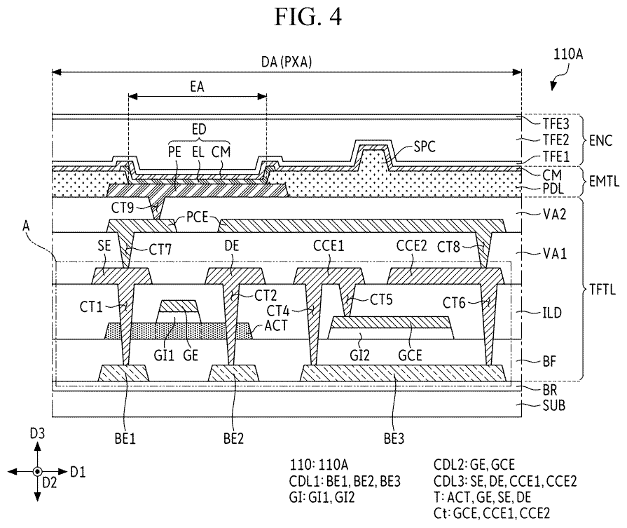

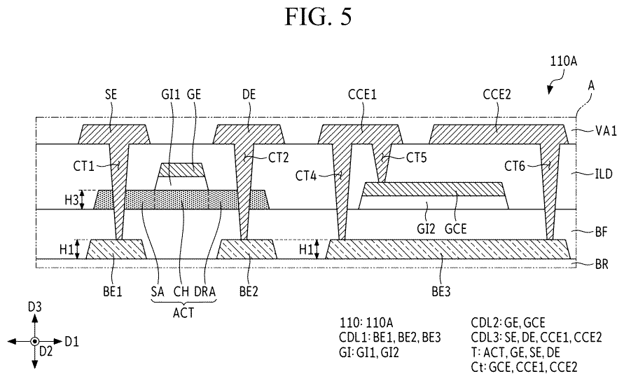

FIG. 4 is a cross-sectional view of the display panel in the display area of FIG. 2. FIG. 5 is an enlarged cross-sectional view of area A of FIG. 4. FIGS. 4 and 5 show the cross-sectional structure of the display panel 110A of the display panel 110 to which the embodiments can be applied.

Referring to FIGS. 4 and 5 in conjunction with FIGS. 1 to 3, the display panel 110 may include a substrate SUB, a transistor layer TFTL, an emission material layer EMTL, and an encapsulation layer ENC. According to an embodiment of the present disclosure, the display panel 110 may further include additional elements provided on and/or under the encapsulation layer ENC. For example, the display panel 110 may further include at least one of a sensor layer (e.g., a touch sensor layer), an optical layer (e.g., a color filter layer and/or a wavelength conversion layer), and a protective layer (e.g., a protective film, an insulating layer, an upper substrate and/or a window). Each of the sensor layer, the optical layer and/or the protective layer may be provided over the encapsulation layer ENC or between the emission material layer EMTL and the encapsulation layer ENC.

The substrate SUB may be a rigid substrate or a flexible substrate that can be bent, folded, or rolled. The substrate SUB may be made of an insulating material such as glass, quartz and a polymer resin. Examples of the polymer material may include polyethersulphone (PES), polyacrylate (PA), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. Alternatively, the substrate SUB may include a metallic material.

A barrier layer BR may be formed on the substrate SUB. The barrier layer BR may be formed on the substrate SUB. In an embodiment, the barrier layer BR may be formed on the entire upper surface of the substrate SUB. The barrier layer BR can protect the transistor layer TFTL and the emission material layer EMTL from moisture permeating through the substrate SUB that is vulnerable to moisture permeation.

The barrier layer BR may include an inorganic insulating material, and may include at least one of silicon nitride, silicon oxide, silicon oxynitride, titanium oxide, and aluminum oxide, for example. In some implementations, the barrier layer BR may be eliminated.

The transistor layer TFTL may be located on the barrier layer BR. The transistor layer TFTL may include circuit elements including transistors T and capacitors C of the pixels PX, and lines (e.g., signal lines and voltage lines). FIG. 4 shows a transistor T and a capacitor Ct disposed in a pixel area PXA as an example of circuit elements that may be provided in the transistor layer TFTL. The transistor T of FIG. 4 may be a driving transistor or a switching transistor provided in the pixel circuit PC of that pixel PX, and the capacitor Ct may be a capacitor provided in the pixel circuit PC of that pixel PX.

The transistor layer TFTL may include a first conductive layer CDL1, a buffer layer BF, a transistor T, a second conductive layer CDL2, a gate insulator GI, an interlayer dielectric layer ILD, a third conductive layer CDL3, first and second via layers VA1 and VA2, and a pixel connection electrode PCE sequentially disposed on the substrate SUB in the third direction D3.

The first conductive layer CDL1 may be located on the barrier layer BR. The first conductive layer CDL1 can suppress a change in the characteristics of the transistor T due to light penetration through the substrate SUB, and can provide electrical stability to the transistor T by having a certain potential.

The first conductive layer CDL1 may work as an etch stopper when a first contact hole CT1, a second contact hole CT2, a fourth contact hole CT4 and a sixth contact hole CT6 are formed in the process of fabricating the display panel 110A. Such a fabrication process will be described later.

The first conductive layer CDL1 may be made up of a single layer or multiple layers of one of molybdenum (Mo), aluminum (Al), chromium (Cr), gold (Au), titanium (Ti), nickel (Ni), neodymium (Nd), copper (Cu) and an alloy thereof.

The first conductive layer CDL1 may include a first bottom electrode BE1, a second bottom electrode BE2, and a third bottom electrode BE3. The first bottom electrode BE1, the second bottom electrode BE2 and the third bottom electrode BE3 may be spaced apart from each other. The first bottom electrode BE1, the second bottom electrode BE2 and the third bottom electrode BE3 may be connected to the source electrode SE, the drain electrode DE, and the first and second connection electrodes CCE1 and CCE2 included in the third conductive layer CDL3, respectively.

In some embodiments, a height H1 (i.e., a thickness) of the first conductive layer CDL1 may range from 1,000 angstroms to 3,000 angstroms.

For example, a height (i.e., a thickness) of the first bottom electrode BE1, a height of the second bottom electrode BE2 and a height of the third bottom electrode BE3 included in the first conductive layer CDL1 may be equal to the height H1 of the first conductive layer CDL1. In an embodiment, the thickness of each of the first to third bottom electrodes BE1 to BE3 may be measured in the third direction D3. In an embodiment, each of the first to third bottom electrodes BE1 to BE3 may have a constant thickness between an upper surface and a lower surface except for a sloped side surface.

The buffer layer BF may be located on the first conductive layer CDL1. The buffer layer BF may be located on the entire surface of the first conductive layer CDL1. The buffer layer BF may entirely cover the first bottom electrode BE1, the second bottom electrode BE2 and the third bottom electrode BE3.

The buffer layer BF can protect the transistor T of the transistor layer TFTL and an emissive layer EL of the emission material layer EMTL from the moisture permeating through the substrate SUB that is vulnerable to moisture permeation.

The buffer layer BF may include an inorganic insulating material, and may include at least one of silicon nitride, silicon oxide, silicon oxynitride, titanium oxide, and aluminum oxide, for example. The buffer layer BF may be implemented as multiple films formed by stacking the above-described inorganic insulating layers alternately.

Although an upper surface of the buffer layer BF is depicted as a flat layer in the drawings for convenience of illustration, the present disclosure is not limited thereto. The buffer layer BF may cover the profile of the underlying structures with a uniform thickness, and accordingly may include different levels. For example, the buffer layer BF may be conformally deposited along the profile of the underlying structures.

The transistor T and the capacitor Ct may be located on the buffer layer BF. The transistor T may include an active layer ACT, a gate electrode GE, a drain electrode DE and a source electrode SE. The capacitor Ct may include a gate connection electrode GCE, a first connection electrode CCE1 and a second connection electrode CCE2. For example, in the capacitor Ct, the gate connection electrode GCE and the first connection electrode CCE1 connected thereto may serve as a first electrode, and the second connection electrode CCE2 may serve a second electrode.

According to the embodiment of the present disclosure, the active layer ACT may be located on the buffer layer BF. The active layer ACT may overlap the first bottom electrode BE1 and the second bottom electrode BE2 in the third direction D3.

The active layer ACT may include an oxide semiconductor. As an example, the active layer ACT may include indium-gallium-zinc oxide (IGZO) or indium-tin-gallium-zinc oxide (ITGZO).

In some embodiments, a height H3 (i.e., a thickness) of the active layer ACT may have a range of 50 angstroms to 500 angstroms. In an embodiment, the height H3 of the active layer ACT may be measured in the third direction D3. In an embodiment, the active layer ACT may have a constant thickness between an upper surface and a lower surface, except for a side surface.

According to the embodiment of the present disclosure, with the height H3 in the above range and the material (e.g., an oxide semiconductor material), the active layer ACT can have high mobility characteristics.

In the display panel 110 according to the embodiment, as the active layer ACT has high-mobility characteristics, the transistor T can be formed in a microscopic size (e.g., a size including the active layer ACT of a width and/or length ranging from approximately several micrometers to several tens of micrometers), while stably obtaining the mobility of the transistor T.

The active layer ACT may include a channel region CH and a source region SA and a drain region DRA spaced apart from each other with the channel region CH therebetween. The source region SA and the drain region DRA may be located on the opposite sides of the channel region CH, respectively. The channel region CH may not be conductive but maintain semiconductor properties. The source region SA and the drain region DRA may be conductive and may have a higher carrier concentration (e.g., electron concentration) than the channel region CH.

According to the embodiment of the present disclosure, the gate insulator GI may be located on the active layer ACT and the buffer layer BF.

The gate insulator GI may include silicon compound or metal oxide. For example, the gate insulator GI may include silicon oxide, silicon nitride, silicon oxynitride, aluminum oxide, tantalum oxide, hafnium oxide, zirconium oxide, or titanium oxide.

The gate insulator GI may include a first gate insulator GI1 and a second gate insulator GI2. The first gate insulator GI1 may be located between the active layer ACTL and the gate electrode GE in contact with them. The first gate insulator GI1 may overlap the channel region CH of the active layer ACT and the gate electrode GE in the third direction D3. The first gate insulator GI1 may expose the source region SA and the drain region DRA of the active layer ACT.

The second gate insulator GI2 may be located on the buffer layer BF. The second gate insulator GI2 may overlap the third bottom electrode BE3 and the gate connection electrode GCE in the third direction D3.

On the plane defined by the first direction D1 and the second direction D2, the first gate insulator GI1 and the second gate insulator GI2 may be an integral insulating pattern connected to each other, or may be individual insulating patterns separated from each other.

The second conductive layer CDL2 may be located on the gate insulator GI. The second conductive layer CDL2 may include the gate electrode GE and the gate connection electrode GCE. The gate electrode GE may be disposed on the first gate insulator GI1 and may overlap the channel region CH. The gate connection electrode GCE may be located on the second gate insulator GI2 and may overlap the third bottom electrode BE3.

The gate electrode GE and the gate connection electrode GCE may be formed as an integral electrode that is connected to each other on the plane defined by the first direction D1 and the second direction D2, but the present disclosure is not limited thereto.

The second conductive layer CDL2 may be made up of a single layer or multiple layers of at least one of: silver (Ag), magnesium (Mg), aluminum (Al), platinum (Pt), lead (Pb), palladium Pd, gold (Au), nickel (Ni), neodymium (Nd), iridium (Ir), chrome (Cr), lithium (Li), calcium (Ca) and a mixture thereof.

Alternatively, the second conductive layer CDL2 may further include a material layer having a high work function, indium-tin-oxide (ITO), indium-zinc-oxide (IZO), zinc oxide (ZnO) and indium oxide (In₂O₃).

The interlayer dielectric layer ILD may be disposed on the second conductive layer CDL2. The interlayer dielectric layer ILD may entirely cover the active layer ACT, the gate insulator GI, and the second conductive layer CDL2.

The interlayer dielectric layer ILD may include an inorganic insulating material. For example, the interlayer dielectric layer ILD may be made of an inorganic insulating material such as silicon oxide, silicon nitride, silicon oxynitride, hafnium oxide, aluminum oxide, titanium oxide, tantalum oxide and zinc oxide.

Although the interlayer dielectric layer ILD is depicted as a flat layer in the drawings for convenience of illustration, the present disclosure is not limited thereto. The interlayer dielectric layer ILD may cover the profile of the underlying structures with a uniform thickness. For example, the interlayer dielectric layer ILD may be conformally deposited along the profile of the underlying structures with a uniform thickness.

The third conductive layer CDL3 may be located on the interlayer dielectric layer ILD. The third conductive layer CDL3 may include the source electrode SE, the drain electrode DE, the first connection electrode CCE1, and the second connection electrode CCE2.

The third conductive layer CDL3 may include a conductive metal. For example, the third conductive layer CDL3 may be made of at least one of: silver (Ag), magnesium (Mg), aluminum (Al), platinum (Pt), lead (Pb), palladium Pd, gold (Au), nickel (Ni), neodymium (Nd), iridium (Ir), chrome (Cr), lithium (Li), calcium (Ca) and a mixture thereof.

According to the embodiment of the present disclosure, the source electrode SE may be directly connected to the active layer ACT and the first bottom electrode BE1 for driving the transistor T and stabilizing the electrical characteristics of the transistor T.

For example, if a contact hole connecting the source electrode SE with the active layer ACT and a contact hole connecting the source electrode SE with the first bottom electrode BE1 are formed spaced apart from each other, a first etching process for forming the contact hole connecting the source electrode SE with the active layer ACT and a second etching process for forming the contact hole connecting the source electrode SE with the first bottom electrode BE1 may be performed separately. It should be noted that if the first etching process and the second etching process are performed separately, the processes may require different masks.

For another example, if the contact hole connecting the source electrode SE with the active layer ACT and the contact hole connecting the source electrode SE with the first bottom electrode BE1 are formed spaced apart from each other, the contact hole connecting the source electrode SE with the active layer ACT and the contact hole connecting the source electrode SE with the first bottom electrode BE1 may be etched simultaneously. However, in this instance, the active layer ACT may be overly etched and thus may have a relatively small thickness, which may result in poor reliability of the display panel.

According to the embodiment of the present disclosure, the first contact hole CT1 is formed such that it penetrates a portion of the active layer ACT in the display panel 110A, so that the active layer ACT and the source electrode SE can be stably connected with each other without over-etching defects of the active layer ACT. As a result, the active layer ACT included in the display panel 110A can stably maintain the height H3 that can ensure high mobility characteristics.

The first bottom electrode BE1 is formed to overlap the source region SA of the active layer ACT in the display panel 110A, so that it is possible to suppress changes in the characteristics of the active layer ACT from light penetration through the substrate SUB. The first bottom electrode BE1 is used as an etch stopper in the process of fabricating the display panel 110A, and thus the process can become easier. Such a fabrication process will be described later.

According to the embodiment of the present disclosure, the drain electrode DE may be directly connected to the active layer ACT and the second bottom electrode BE2 for driving the transistor T and stabilizing the electrical characteristics.

According to the embodiment of the present disclosure, the second contact hole CT2 is formed such that it penetrates a portion of the active layer ACT in the display panel 110A, so that the active layer ACT and the drain electrode DE can be stably connected with each other without over-etching defects of the active layer ACT. As a result, the active layer ACT included in the display panel 110A can stably maintain the height H3 that can ensure high mobility characteristics.

The second bottom electrode BE2 is formed to overlap the drain region DRA of the active layer ACT in the display panel 110A, so that it is possible to suppress changes in the characteristics of the active layer ACT from light penetration through the substrate SUB. The second bottom electrode BE2 is used as an etch stopper in the process of fabricating the display panel 110A, and thus the process can become easier. Such a fabrication process will be described later.

One side of the first connection electrode CCE1 may be connected to the third bottom electrode BE3 through the fourth contact hole CT4 penetrating the interlayer dielectric layer IDL and the buffer layer BF, and the other side of the first connection electrode CCE1 may be connected to the gate connection electrode GCE through the fifth contact hole CT5 penetrating the interlayer dielectric layer ILD. The third bottom electrode BE3 and the gate connection electrode GCE may be electrically connected through the first connection electrode CCE1. In an embodiment, the first connection electrode CCE1 may include a horizontal conductive pattern, a first vertical extension, and a second vertical extension. The horizontal conductive pattern may extend in the first direction D1 and may be disposed on an upper surface of the interlayer dielectric layer ILD. The first vertical extension may extend in the third direction D3 from a lower surface of the horizontal conductive pattern toward an upper surface of the substrate SUB. The second vertical extension may extend in the third direction D3 from the lower surface of the horizontal conductive pattern toward an upper surface of the substrate SUB. The one side of the first connection electrode CCE1 corresponds to the first vertical extension, and the other side of the first connection electrode CCE1 corresponds to the second vertical extension.

The second connection electrode CCE2 may be electrically connected to the third bottom electrode BE3 through a sixth contact hole CT6 penetrating the interlayer dielectric layer ILD and the buffer layer BF.

A first via layer VA1 may be located on the third conductive layer CDL3. The first via layer VA1 may entirely cover the third conductive layer CDL3. The first via layer VA1 may provide a flat surface over the third conductive layer CDL3 having different levels.

The first via layer VIA1 may include an organic material. For example, the first via layer VIA1 may include at least one of an acryl resin, an epoxy resin, a phenolic resin, a polyamide resin and a polyimide resin.

The pixel connection electrode PCE may be located on the first via layer VA1. There may be a plurality of pixel connection electrodes PCE. At least one pixel connection electrode PCE may be connected to the source electrode SE through a seventh contact hole CT7 penetrating the first via layer VA1, and another pixel connection electrode PCE may be connected to the second connection electrode CCE2 through an eighth contact hole CT8 penetrating the first via layer VA1.

A second via layer VA2 may be located on the pixel connection electrode PCE. The second via layer VA2 may include the same material and structure as the first via layer VA1.

The emission material layer EMTL may be located on the second via layer VA2. The emission material layer EMTL may include a pixel-defining layer PDL and a light-emitting element ED stacked in the third direction D3. The light-emitting element ED may include a pixel electrode PE, an emissive layer EL, and a common electrode CM.

In the emission area EA, the pixel electrode PE, the emissive layer EL and the common electrode CM are stacked on one another sequentially, so that holes from the pixel electrode PE and electrons from the common electrode CM are combined with each other in the emissive layer EL to emit light. In this instance, the pixel electrode PE may be an anode electrode of the light-emitting element ED, and the common electrode CM may be a cathode electrode of the light-emitting element ED.

The pixel electrode PE of the light-emitting element ED may be located on the second via layer VA2. The pixel electrode PE may be connected to the pixel connection electrode PCE through a ninth contact hole CT9 penetrating the second via layer VA2.

The pixel electrode PE may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/AI/ITO), an APC alloy and a stack structure of an APC alloy and ITO (ITO/APC/ITO) in order to increase the reflectivity. The APC alloy may be an alloy of silver (Ag), palladium (Pd) and copper (Cu).

The pixel-defining layer PDL may define the emission area EA of the pixel. The pixel-defining layer PDL may cover the edges of the pixel electrode PE.

The pixel-defining layer PDL may include an organic material, e.g., an acryl resin, an epoxy resin, a phenolic resin, a polyamide resin, or a polyimide resin.

A spacer SPC may be disposed on the pixel-defining layer PDL. The spacer SPC may support a mask during a process of fabricating the emissive layer EL.

The spacer SPC may include an organic material, e.g., an acryl resin, an epoxy resin, a phenolic resin, a polyamide resin or a polyimide resin. In some implementations, the spacer SPC may be formed integrally with the pixel-defining layer PDL.

The emissive layer EL of the light-emitting element ED may be located on the pixel electrode PE. The emissive layer EL may include an organic material to emit light of a certain color. For example, the emissive layer EL may include a hole transporting layer, an organic material layer, and an electron transporting layer. The organic material layer may include a host and a dopant. The organic material layer may include a material that emits a predetermined light, and may be formed using a phosphor or a fluorescent material.

The common electrode CM of the light-emitting element ED may be located on the emissive layer EL. The common electrode CM may be located on the emissive layer EL to cover it. The common electrode CM may be a common layer disposed across a plurality of emissive layers EL. Although not shown in the drawings, a capping layer may be formed on the common electrode CM.

The common electrode CM may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode CM is formed of a semi-transmissive metal material, the light extraction efficiency can be increased by using microcavities.

The encapsulation layer ENC may be formed on the emission material layer EMTL. The encapsulation layer ENC may include one or more inorganic films to prevent permeation of oxygen or moisture into the emission material layer EMTL, and may include at least one organic film to protect the emission material layer EMTL from particles such as dust.

The encapsulation layer ENC may include a first encapsulation layer TFE1, a second encapsulation layer TFE2 and a third encapsulation layer TFE3.

The first encapsulation layer TFE1 may be located on the common electrode CM and may entirely cover the common electrode CM. The first encapsulation layer TFE1 may include an inorganic insulating material, and may be implemented as multiple films formed by alternately stacking one or more inorganic films, e.g., a silicon nitride layer, a silicon oxynitride layer, a silicon oxide layer, a titanium oxide layer and an aluminum oxide layer.

The second encapsulation layer TFE2 may be located on the first encapsulation layer TFE1 and may cover the first encapsulation layer TFE1. In an embodiment, the second encapsulant layer TFE2 may cover the entire upper surface of the first encapsulation layer TFE1. The second encapsulation layer TFE2 may provide a flat surface over the first encapsulation layer TFE1.

The second encapsulation layer TFE2 may include an organic material, and may be, for example, an organic film such as an acrylic resin, an epoxy resin, a silicone resin, a silicone-acryl resin, a phenolic resin, a polyamide resin, and a polyimide resin.

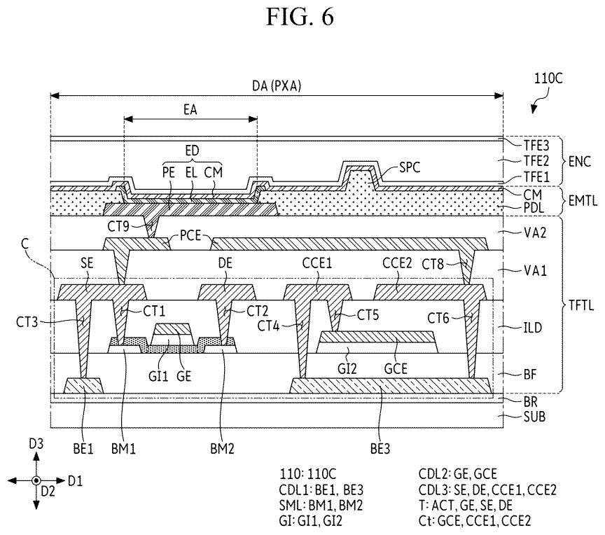

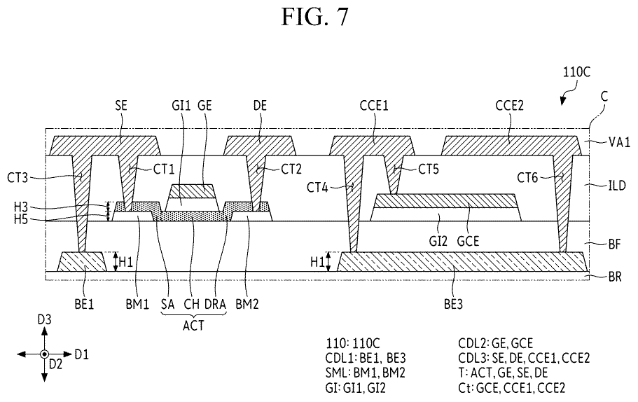

FIG. 6 is a cross-sectional view of the display panel in the display area of FIG. 2 according to another embodiment. FIG. 7 is an enlarged, cross-sectional view of area C of FIG. 6.

Referring to FIGS. 6 and 7, the transistor layer TFTL included in the display panel 110C may have a different shape from the transistor layer TFTL included in the display panel 110A. Specifically, the transistor layer TFTL included in the display panel 110C may include a subsidiary metal layer SML between the buffer layer BF and the active layer ACT by adding a separate process.

In the following description, description will focus on the difference between the display panel 110C and the display panel 110A and the redundant description will be omitted.

The transistor layer TFTL of the display panel 110C may include a first conductive layer CDL1, a buffer layer BF, a subsidiary metal layer SML, a transistor T, a second conductive layer CDL2, a gate insulator GI, an interlayer dielectric layer ILD, a third conductive layer CDL3, first and second via layers VA1 and VA2, and a pixel connection electrode PCE sequentially disposed on the substrate SUB in the third direction D3.

The first conductive layer CDL1 of the display panel 110C may include a first bottom electrode BE1 and a third bottom electrode BE3. The first bottom electrode BE1 and the third bottom electrode BE3 may be spaced apart from each other. The first bottom electrode BE1 may be connected to one side of the source electrode SE included in the transistor T, and the third bottom electrode BE3 may be connected to one side of the first connection electrode CCE1 and the second connection electrode CCE2 which are included in the capacitor Ct. By applying a certain potential to the first bottom electrode BE1 and the third bottom electrode BE3, it is possible to provide electrical stability to the transistor T and the capacitor Ct.

In some embodiments, the height H1 of the first conductive layer CDL1 may range from 1,000 angstroms to 3,000 angstroms. For example, the height of the first bottom electrode BE1 and the height of the third bottom electrode BE3 included in the first conductive layer CDL1 may be equal to the height H1 of the first conductive layer CDL1.

The subsidiary metal layer SML may be located on the buffer layer BF. The subsidiary metal layer SML may be located between the buffer layer BF and the active layer ACT in contact with them. The subsidiary metal layer SML can block the introduction of light into the active layer ACT and may work as an etch stopper in a process of forming the first contact hole CT1 and the second contact hole CT2 of the display panel 110C.

The subsidiary metal layer SML may include a first auxiliary metal BM1 and a second auxiliary metal BM2. The first auxiliary metal BM1 and the second auxiliary metal BM2 may be spaced apart from each other with a channel region CH of the active layer ACT therebetween. For example, the first auxiliary metal BM1 may be located in line with the source region SA of the active layer ACT, and the second auxiliary metal BM2 may be located in line with the drain region DRA.

The subsidiary material layer SML may be made of at least one of silver (Ag), magnesium (Mg), aluminum (Al), platinum (Pt), lead (Pb), palladium Pd, gold (Au), nickel (Ni), neodymium (Nd), iridium (Ir), chrome (Cr), lithium (Li), calcium (Ca) and a mixture thereof.

In some embodiments, a height H5 (i.e., a thickness) of the subsidiary metal layer SML may be equal to or smaller than the height H1 of the first conductive layer CDL1. For example, a height (i.e., a thickness) of the first auxiliary metal BM1 and a height (i.e., a thickness) of the second auxiliary metal BM2 included in the subsidiary metal layer SML may be equal to the height H5 of the subsidiary metal layer SML. In an embodiment, the height H5 of the subsidiary metal layer SML may be measured in the third direction D3. In an embodiment, the subsidiary metal layer SML may have a constant thickness between an upper surface and a lower surface, except for a side surface.

The active layer ACT may be located on the buffer layer BF and the subsidiary metal layer SML. For example, the active layer ACT may be entirely in contact with the first auxiliary metal BM1 and the second auxiliary metal BM2. The active layer ACT may cover along the profile formed by the subsidiary metal layer SML and the buffer layer BF.

In some embodiments, the active layer ACT may be formed of a high mobility oxide semiconductor, and the height H3 of the active layer ACT may have a range of 50 angstroms to 500 angstroms. The redundant descriptions will be omitted.

One side of the source electrode SE included in the display panel 110C may be in contact with the source region SA of the active layer ACT through the first contact hole CT1 penetrating the interlayer dielectric layer ILD and the active layer ACT, and also with the first auxiliary metal BM1.

The other side of the source electrode SE included in the display panel 110C may be electrically connected to the first bottom electrode BE1 through a third contact hole CT3 penetrating the interlayer dielectric layer ILD and the buffer layer BF. In an embodiment, the source electrode SE may include a horizontal conductive pattern, a first vertical extension, and a second vertical extension. The horizontal conductive pattern may extend in the first direction D1 and may be disposed on an upper surface of the interlayer dielectric layer ILD. The first vertical extension may extend in the third direction D3 from a lower surface of the horizontal conductive pattern toward the upper surface of the substrate SUB. The second vertical extension may extend in the third direction D3 from the lower surface of the horizontal conductive pattern toward the upper surface of the substrate SUB. The one side of the source electrode SE corresponds to the first vertical extension, and the other side of the source electrode SE corresponds to the second vertical extension.

The drain electrode DE included in the display panel 110C may be in contact with the drain region DRA of the active layer ACT through the second contact hole CT2 penetrating the interlayer dielectric layer ILD and the active layer ACT, and also with the second auxiliary metal BM2. The other common structures will not be described to avoid redundancy.

In the display panel 110C, the subsidiary metal layer SML is formed under the active layer ACT in contact with it, so that it is possible to suppress changes in the characteristics of the active layer ACT from light penetration through the substrate SUB.

As the first contact hole CT1 and the second contact hole CT2 are formed such that they penetrate a portion of the active layer ACT in the display panel 110C, so that the active layer ACT and the third conductive layer CDL3 can be stably connected to each other without over-etching defects of the active layer ACT. As a result, the active layer ACT included in the display panel 110C can stably maintain the height H3 that can ensure high mobility characteristics.

The subsidiary metal layer SML is used as an etch stopper in the process of fabricating the display panel 110C, and thus the process can become easier.

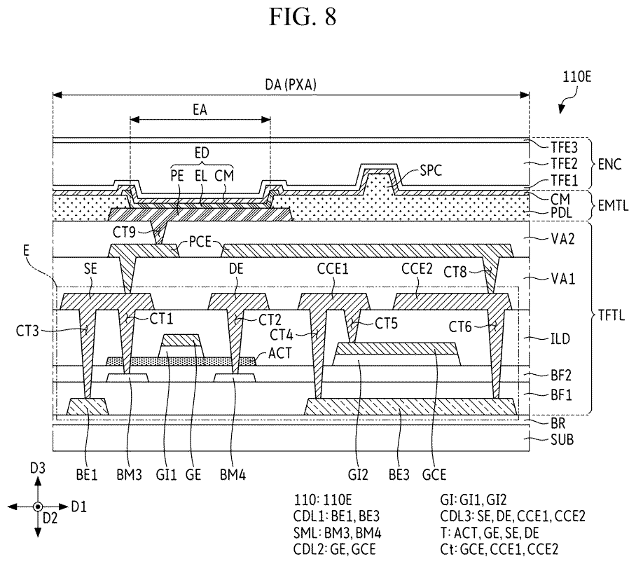

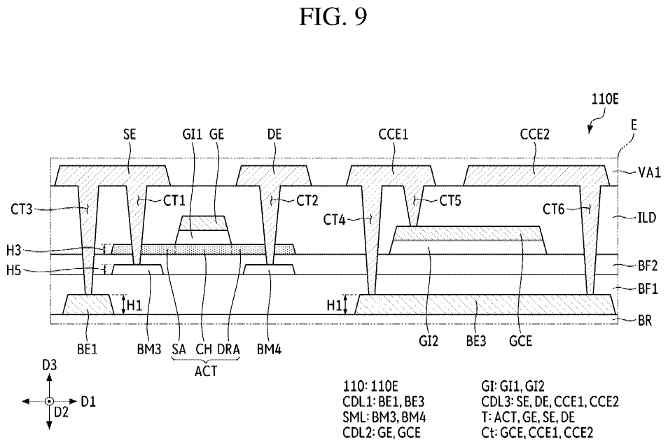

FIG. 8 is a cross-sectional view of the display panel in the display area of FIG. 2 according to yet another embodiment. FIG. 9 is an enlarged cross-sectional view of area E of FIG. 8.

Referring to FIGS. 8 and 9, the transistor layer TFTL included in the display panel 110E may have a different shape from the transistor layer TFTL included in the display panel 110A. Specifically, the transistor layer TFTL included in the display panel 110E may include a first buffer layer BF1 and a second buffer layer BF2, and may further include a subsidiary metal layer SML located between the first buffer layer BF1 and the second buffer layer BF2.

In the following description, description will focus on the difference between the display panel 110E and the display panel 110A and the redundant description will be omitted.

The transistor layer TFTL of the display panel 110E may include the first conductive layer CDL1, the first buffer layer BF1, the subsidiary metal layer SML, the second buffer layer BF2, the transistor T, the second conductive layer CDL2, the gate insulator GI, the interlayer dielectric layer ILD, the third conductive layer CDL3, the first and second via layers VA1 and VA2, and the pixel connection electrode PCE sequentially disposed on the substrate SUB in the third direction D3.

The first conductive layer CDL1 of the display panel 110E may include a first bottom electrode BE1 and a third bottom electrode BE3. The first bottom electrode BE1 and the third bottom electrode BE3 may be spaced apart from each other. The first bottom electrode BE1 may be connected to one side of the source electrode SE included in the transistor T, and the third bottom electrode BE3 may be connected to one side of the first connection electrode CCE1 and the second connection electrode CCE2 which are included in the capacitor Ct. By applying a certain potential to the first bottom electrode BE1 and the third bottom electrode BE3, it is possible to provide electrical stability to the transistor T and the capacitor Ct by virtue of the first bottom electrode BE1 and the third bottom electrode BE3.

In some embodiments, the height H1 of the first conductive layer CDL1 may range from 1,000 angstroms to 3,000 angstroms. For example, the height of the first bottom electrode BE1 and the height of the third bottom electrode BE3 included in the first conductive layer CDL1 may be equal to the height H1 of the first conductive layer CDL1.

The first buffer layer BF1 may be located on the first conductive layer CDL1. The first buffer layer BF1 may entirely cover the first bottom electrode BE1 and the third bottom electrode BE3. The first buffer layer BF1 may include the same material as the buffer layer BF of the display panel 110A.

The subsidiary metal layer SML may be located on the first buffer layer BF1. The subsidiary metal layer SML may be spaced apart from the active layer ACT. The subsidiary metal layer SML can block the introduction of light into the active layer ACT and may work as an etch stopper in a process of forming the first contact hole CT1 and the second contact hole CT2 of the display panel 110E.

The subsidiary metal layer SML may include a first subsidiary metal BM3 and a second subsidiary metal BM4. The first auxiliary metal BM3 and the second auxiliary metal BM4 may be spaced apart from each other. For example, the first auxiliary metal BM3 may be located in line with the source region SA of the active layer ACT, and the second auxiliary metal BM4 may be located in line with the drain region DRA.

The subsidiary material layer SML may be made of at least one of silver (Ag), magnesium (Mg), aluminum (Al), platinum (Pt), lead (Pb), palladium Pd, gold (Au), nickel (Ni), neodymium (Nd), iridium (Ir), chrome (Cr), lithium (Li), calcium (Ca) and a mixture thereof.

In some embodiments, the height H5 of the subsidiary metal layer SML may be equal to or smaller than the height H1 of the first conductive layer CDL1. For example, the height of the first auxiliary metal BM3 and the height of the second auxiliary metal BM4 included in the subsidiary metal layer SML may be equal to the height H5 of the subsidiary metal layer SML.

The second buffer layer BF2 may be located on the subsidiary metal layer SML. The second buffer layer BF2 may entirely cover the first auxiliary metal BM3 and the second auxiliary metal BM4. The second buffer layer BF2 may include the same material as the first buffer layer BF1.

The active layer ACT may be disposed on the second buffer layer BF2. For example, the active layer ACT may be spaced apart from the subsidiary metal layer SML in the third direction D3 with the second buffer layer BF2 therebetween. The active layer ACT may overlap the first auxiliary metal BM3 and the second auxiliary metal BM4 in the third direction D3.

In some embodiments, the active layer ACT may include oxide semiconductor, and the height H3 of the active layer ACT may have a range of 50 angstroms to 500 angstroms. The redundant descriptions will be omitted.

One side of the source electrode SE included in the display panel 110E may be in contact with the source region SA of the active layer ACT through the first contact hole CT1 penetrating the interlayer dielectric layer ILD, the second buffer layer BF2 and the active layer ACT, and also with the first auxiliary metal BM3 through the first contact hole CT1.

The other side of the source electrode SE included in the display panel 110E may be electrically connected to the first bottom electrode BE1 through a third contact hole CT3 penetrating the interlayer dielectric layer ILD, the first buffer layer BF1 and the second buffer layer BF2.

The drain electrode DE included in the display panel 110E may be in contact with the drain region DRA of the active layer ACT through the second contact hole CT2 penetrating the interlayer dielectric layer ILD, the second buffer layer BF2 and the active layer ACT, and also with the second auxiliary metal BM4 through the second contact hole CT2.

In the display panel 110E, the subsidiary metal layer SML overlaps the active layer ACT in the third direction D3, so that it is possible to suppress changes in the characteristics of the active layer ACT from light penetration through the substrate SUB. It should be noted that the subsidiary metal layer SML included in the display panel 110E may be spaced apart from the active layer ACT in the third direction D3.

As the first contact hole CT1 and the second contact hole CT2 are formed such that they penetrate the portions of the active layer ACT in the display panel 110E, the active layer ACT and the third conductive layer CDL3 can be stably connected to each other without over-etching defects of the active layer ACT. As a result, the active layer ACT included in the display panel 110E can stably maintain the height H3 that can ensure high mobility characteristics.

The subsidiary metal layer SML is used as an etch stopper in the process of fabricating the display panel 110E, and thus the process can become easier.

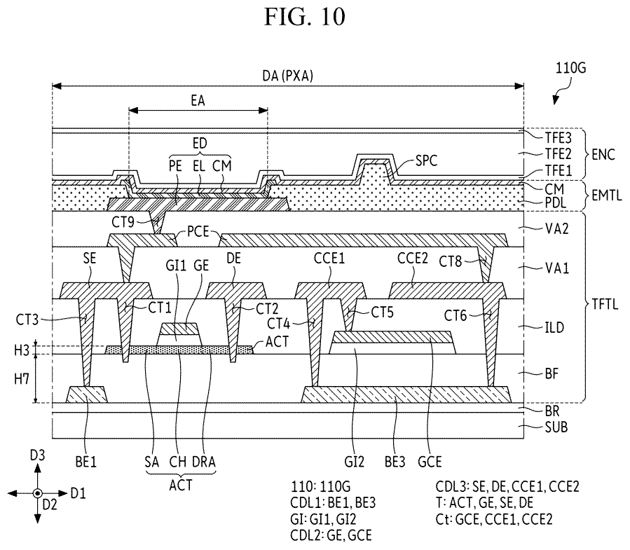

FIG. 10 is a cross-sectional view of the display panel in the display area of FIG. 2 according to yet another embodiment.

Referring to FIG. 10, the transistor layer TFTL included in the display panel 110G may have a different shape from the transistor layer TFTL included in the display panel 110A. Specifically, the transistor layer TFTL included in the display panel 110G may include contact holes penetrating the active layer ACT, but may not include a metal layer working as a separate etch stopper.

In the following description, description will focus on the difference between the display panel 110G and the display panel 110A and the redundant description will be omitted.

The transistor layer TFTL of the display panel 110G may include a first conductive layer CDL1, a buffer layer BF, a transistor T, a second conductive layer CDL2, a gate insulator GI, an interlayer dielectric layer ILD, a third conductive layer CDL3, first and second via layers VA1 and VA2, and a pixel connection electrode PCE sequentially disposed on the substrate SUB in the third direction D3.

The first conductive layer CDL1 of the display panel 110G may include a first bottom electrode BE1 and a third bottom electrode BE3. The first bottom electrode BE1 and the third bottom electrode BE3 may be spaced apart from each other. The first bottom electrode BE1 may be connected to one side of the source electrode SE included in the transistor T, and the third bottom electrode BE3 may be connected to one side of the first connection electrode CCE1 and the second connection electrode CCE2 which are included in the capacitor Ct. By applying a certain potential to the first bottom electrode BE1 and the third bottom electrode BE3, it is possible to provide electrical stability to the transistor T and the capacitor Ct by virtue of the first bottom electrode BE1 and the third bottom electrode BE3.

The buffer layer BF may be located on the first conductive layer CDL1. The buffer layer BF may separate the first conductive layer CDL1 from the active layer ACT. The buffer layer BF may work as an etch stopper when the first contact hole CT1 and the second contact hole CT2 are formed in the process of fabricating the display panel 110G. Therefore, the buffer layer BF included in the display panel 110G may have such a thickness that it can work as an etch stopper. In some embodiments, a height H7 (i.e., a thickness) of the buffer layer BF may range from 1,000 angstroms to 1500 angstroms.

The active layer ACT may be located on the buffer layer BF. The active layer ACT may include oxide semiconductor, and the height H3 of the active layer ACT may have a range of 50 angstroms to 500 angstroms. The redundant descriptions will be omitted.

One side of the source electrode SE included in the display panel 110G may be in contact with the source region SA of the active layer ACT through the first contact hole CT1 penetrating the interlayer dielectric layer ILD and a portion of the active layer ACT. The first contact hole CT1 may be extended from the portion of the active layer ACT to penetrate a portion of the buffer layer BF. The first contact hole CT1 may penetrate the buffer layer BF not entirely but partially.

The other side of the source electrode SE included in the display panel 110G may be electrically connected to the first bottom electrode BE1 through a third contact hole CT3 penetrating the interlayer dielectric layer ILD and the buffer layer BF.

The drain electrode DE included in the display panel 110G may be in contact with the drain region DRA of the active layer ACT through the second contact hole CT2 penetrating the interlayer dielectric layer ILD and the active layer ACT. The second contact hole CT2 may be extended from the portion of the active layer ACT to penetrate a portion of the buffer layer BF. The second contact hole CT2 may penetrate the buffer layer BF not entirely but partially.

As the first contact hole CT1 and the second contact hole CT2 are formed such that they penetrate the portions of the active layer ACT in the display panel 110G, the active layer ACT and the third conductive layer CDL3 can be stably connected to each other without over-etching defects of the active layer ACT. As a result, the active layer ACT included in the display panel 110G can stably maintain the height H3 that can ensure high mobility characteristics.

The display panel 110G can stably control the etching process without any additional process by using the buffer layer BF as an etch stopper during the process of fabricating the first contact hole CT1 and the second contact hole CT2. Therefore, the process of forming the display panel 110G can become easier.

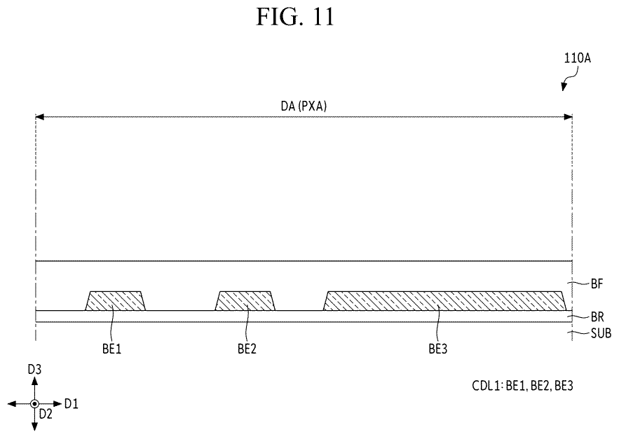

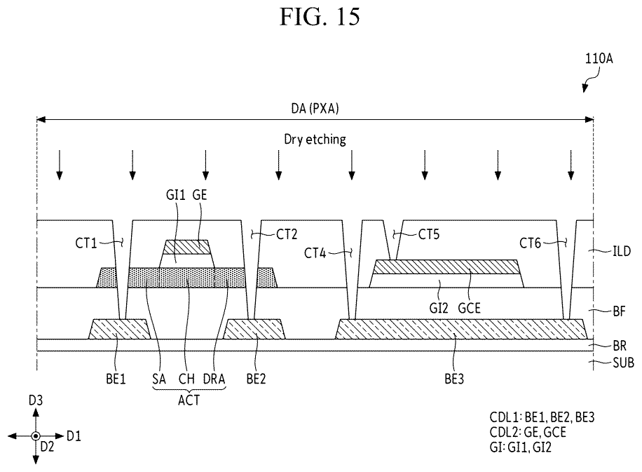

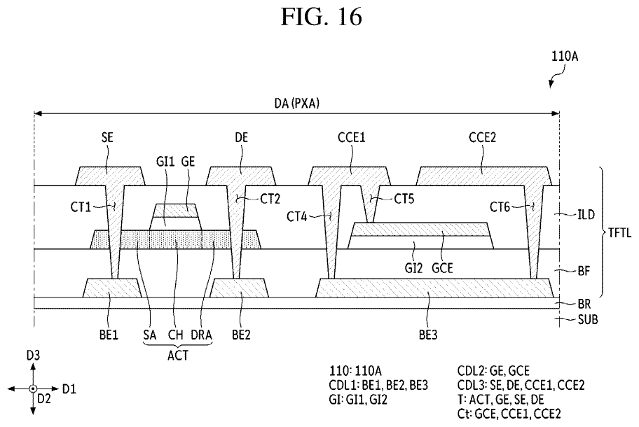

FIGS. 11 to 16 are flowcharts showing a method for fabricating a portion of the transistor layer included in the display panel of FIG. 4. For example, FIGS. 11 to 16 sequentially show forming a transistor T and a capacitor Ct included in the transistor layer TFTL.

Referring to FIG. 11, a substrate SUB including a display area DA is prepared. Then, a barrier layer BR may be formed on the substrate SUB optionally. The display area DA may include a pixel area PXA.

Subsequently, a first conductive layer CDL1 including a first bottom electrode BE1, a second bottom electrode BE2 and a third bottom electrode BE3 is formed on the barrier layer BR (or substrate SUB), and then the first conductive layer CDL1 is covered with a buffer layer BF.

In this process, the first conductive layer CDL1 may be formed via a photolithography process. Specifically, the first conductive layer CDL1 may be formed by a film forming process including at least one conductive material (e.g., a deposition process) and a patterning process (e.g., an etching process using a mask).

Subsequently, the buffer layer BF that entirely covers the first conductive layer CDL1 is formed. The buffer layer BF may be formed by chemical vapor deposition (CVD) or physical vapor deposition (PVD).

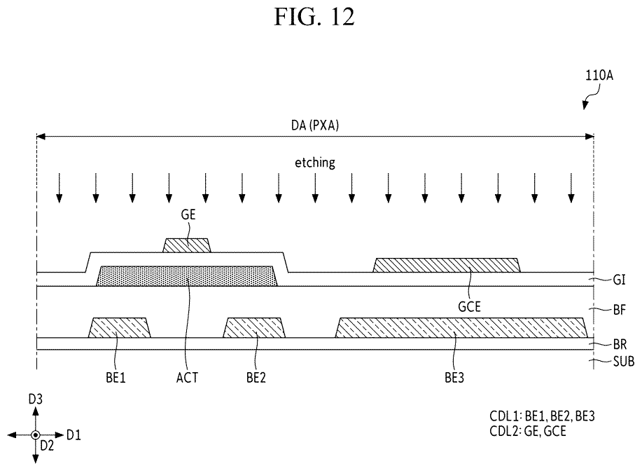

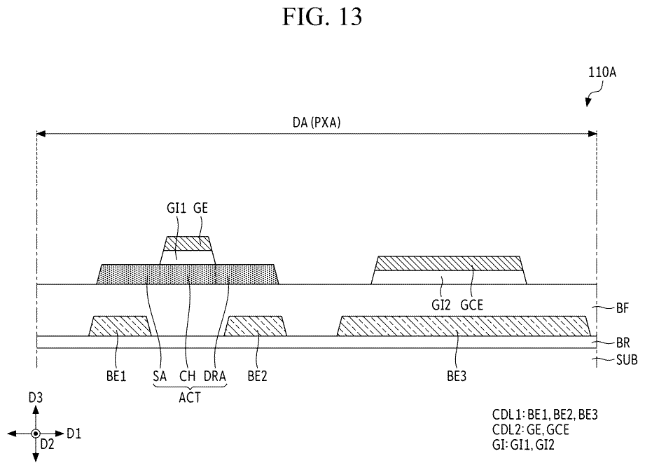

Subsequently, referring to FIGS. 12 and 13, an active layer ACT is formed on the buffer layer BF. The active layer ACT may overlap the first bottom electrode BE1 and the second bottom electrode BE2 in the third direction D3.

In this process, the active layer ACT may be formed via a photolithography process. Specifically, the active layer ACT may be formed by a semiconductor film forming process using at least one oxide semiconductor and a patterning process (e.g., an etching process using a mask). In this process, the active layer ACT may have a height in a certain range for high mobility characteristics. The redundant descriptions will be omitted.

Subsequently, a gate insulator GI is formed on the active layer ACT. In this process, the gate insulator GI may entirely cover the active layer ACT and the buffer layer BF.

Subsequently, a second conductive layer CDL2 including a gate electrode GE and a gate connection electrode GCE is formed on the gate insulator GI. In this process, the gate electrode GE may be formed at a position in line with the active layer ACT in the third direction D3, and the gate connection electrode GCE may be formed at a position in line with the third bottom electrode BE3 in the third direction D3.

Subsequently, an etching process is conducted to remove a part of the gate insulator GI. This etching process may be carried out using a separate mask or using the second conductive layer CDL2 as a etch mask. In case that the second conductive layer CDL2 serves as a etch mask, the gate insulator GI may be patterned into a first gate insulator GI1 and a second gate insulator GI2 using the gate electrode GE and the gate connection electrode GCE of the second conductive layer CDL2 as the etch mask, respectively. The shapes of the gate electrode GE and the gate connection electrode GCE may be transferred into the first gate insulator GI1 and the second gate insulator GI2.

In this process, the nature of the active layer ACT may be changed so that it has different portions having different characteristics. Specifically, in this process, oxygen vacancies may occur at portions of the active layer ACT that does not overlap the gate electrode GE or the first gate insulator GI1. Accordingly, the active layer ACT may be divided into multiple regions (e.g., a channel region CH, a source region SA and a drain region DRA having different characteristics. In some implementations, the oxygen vacancy of the active layer ACT may diffuse even to the channel region CH. For example, the oxygen vacancies in the oxide semiconductor material of the active layer ACT may be defects where oxygen atoms are missing from their lattice positions in the crystal structure of the oxide semiconductor material. The oxygen vacancies may serve as donor defects, introducing free electrons into the source region SA and the drain region DRA where the oxygen vacancies are formed during the etch process of patterning the gate insulator layer GI into the first and second gate insulators GI1 and GI2, thereby enhancing n-type conductivity or making conductive.

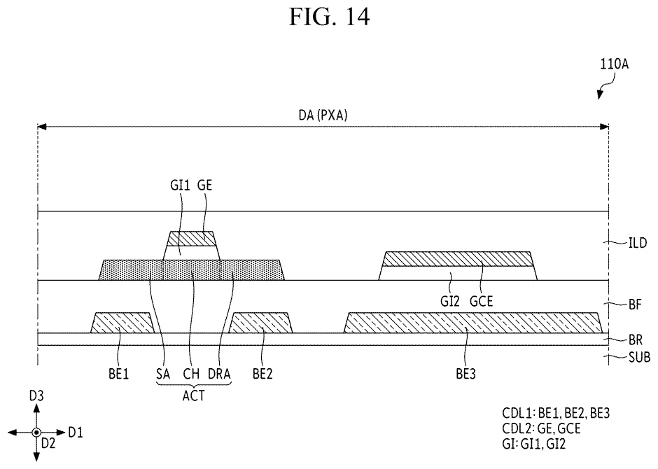

Subsequently, referring to FIGS. 14 to 16, an interlayer dielectric layer ILD is formed on the second conductive layer CDL2. The interlayer dielectric layer ILD may entirely cover the second conductive layer CDL2 and the gate insulator GI. The interlayer dielectric layer ILD may be formed by chemical vapor deposition (CVD) or physical vapor deposition (PVD). Accordingly, the process of forming the interlayer dielectric layer ILD may use hydrogen gas during the process and may include a heat treatment process before and after the process.

In this process, hydrogen may be introduced into a part of the active layer ACT. Hydrogen may be introduced by the process of forming the interlayer dielectric layer ILD. In an embodiment, hydrogen may react with oxygen in the lattice to form H20, which desorbs from the surface of the active layer ACT, leaving behind oxygen vacancies. Therefore, the part of the active layer ACT may be made conductive (e.g., become the n-type) with respect to the portions containing a large number of oxygen vacancies (e.g., the source region SA and the drain region DRA).

Subsequently, a plurality of contact holes may be formed through the interlayer dielectric layer ILD and the buffer layer BF. The plurality of contact holes may be formed by an etching process, and for example, may be formed by a dry etching process.

In this process, the first contact hole CT1 and the second contact hole CT2 overlapping the active layer ACT may be formed substantially simultaneously via a single mask process.

In some embodiments, a fourth contact hole CT4, a fifth contact hole CT5 and a sixth contact hole CT6 not overlapping the active layer ACT may be formed simultaneously with the first contact hole CT1 and the second contact hole CT2 via a single mask process, but the present disclosure is not limited thereto.

In the present process, the first contact hole CT1 and the second contact hole CT2 may penetrate a part of the active layer ACT. In other words, the first contact hole CT1 and the second contact hole CT2 may be extended through the interlayer dielectric layer ILD, the active layer ACT and the buffer layer BF. For example, the first contact hole CT1 may penetrate a part of the source region SA of the active layer ACT, and the second contact hole CT2 may penetrate a part of the drain region DRA of the active layer ACT.

As described above, in the display panel 110A according to the embodiment of the present disclosure, the first contact hole CT1 and the second contact hole CT2 penetrate the active layer ACT, so that it is possible to prevent the active layer ACT from being overetched. Therefore, the active layer ACT included in the display panel 110A can stably maintain the height that can ensure high mobility characteristics. The redundant descriptions will be omitted.

The first conductive layer CDL1 is used as an etch stopper in the process of fabricating the display panel 110A, so that the etching degree can be stably controlled without any additional process. Therefore, the process of forming the display panel 110A can become easier.

Subsequently, a third conductive layer CDL3 may be formed on the interlayer dielectric layer ILD. The third conductive layer CDL3 may include a source electrode SE, a drain electrode DE, a first connection electrode CCE1, and a second connection electrode CCE2.

Patterns of the third conductive layer CDL3 including the source electrode SE, the drain electrode DE, the first connection electrode CCE1 and/or the second connection electrode CCE2 (e.g., the electrodes, the conductive patterns and/or at least one line provided in the third conductive layer CDL3) may be formed by a film forming process (e.g., a deposition process) using at least one conductive material listed above and a patterning process (e.g., an etching process using a mask).

In this process, the source electrode SE may be in contact with the active layer ACT through the first contact hole CT1 and also with the first bottom electrode BE1. The drain electrode DE may be in contact with the active layer ACT through the second contact hole CT2 and also with the second bottom electrode BE2.

In this process, one side of the first connection electrode CCE1 may be in contact with the third bottom electrode BE3 through the fourth contact hole CT4, and the other side of the first connection electrode CCE1 may be in contact with the gate connection electrode GCE through the fifth contact hole CT5. Accordingly, the third bottom electrode BE3 and the gate connection electrode GCE may be electrically connected through the first connection electrode CCE1. The second connection electrode CCE2 may be in contact with the third bottom electrode BE3 through the sixth contact hole CT6.

In this manner, the part of the thin-film transistor layer TFTL including the transistor T and the capacitor Ct in the display panel 110A can be formed.

The display device according to one embodiment of the present disclosure can be applied to various electronic devices. The electronic device according to the one embodiment of the present disclosure includes the display device described above, and may further include modules or devices having additional functions in addition to the display device.

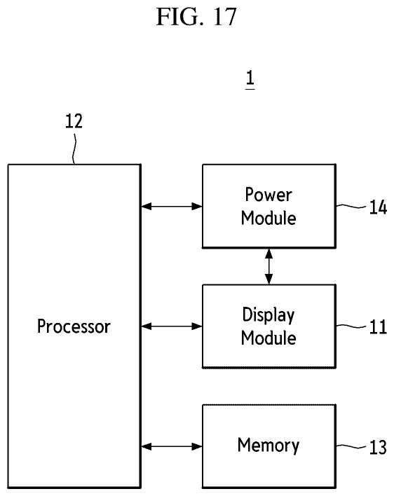

FIG. 17 is a block diagram of an electronic device according to one embodiment of the present disclosure.

Referring to FIG. 17, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

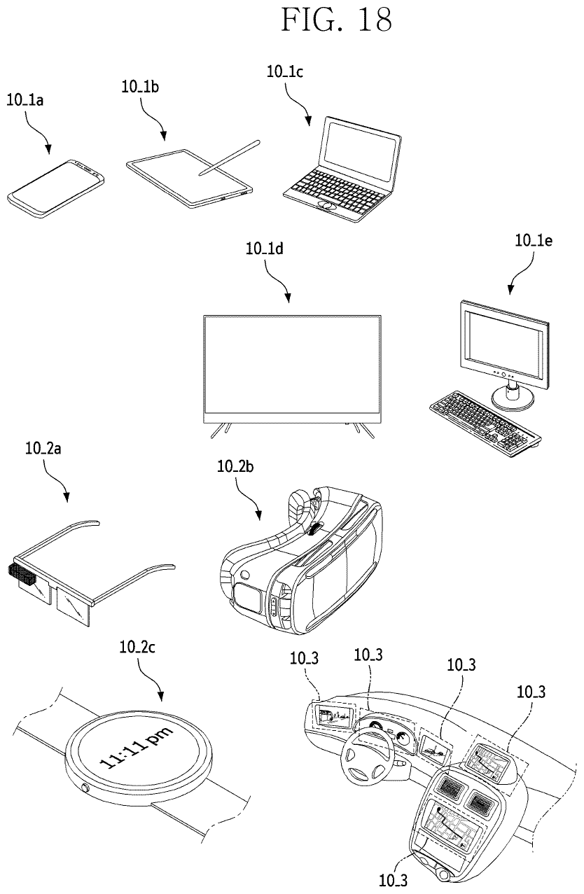

FIG. 18 is a schematic diagram of an electronic device according to various embodiments of the present disclosure.

Referring to FIG. 18, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

What is claimed is:

1. A display device comprising:
a substrate;
a first conductive layer disposed on the substrate and comprising a first bottom electrode and a second bottom electrode; and
a transistor disposed on the first conductive layer,
wherein the transistor comprises:
an active layer comprising a source region, a channel region, and a drain region;
a second conductive layer comprising a gate electrode disposed on the channel region of the active layer;
a third conductive layer disposed on the second conductive layer and comprising a source electrode and a drain electrode;
a first contact hole penetrating the source region of the active layer and exposing a first inner side surface of the source region and an upper surface of the first bottom electrode; and
a second contact hole penetrating the drain region of the active layer and exposing a second inner side surface of the drain region and the second bottom electrode,
wherein the source electrode fills the first contact hole and contacts the first inner side surface of the source region and the upper surface of the first bottom electrode, and
wherein the drain electrode fills the second contact hole and contacts the second inner side surface of the drain region and the upper surface of the second bottom electrode.

2. The display device of claim 1,
wherein the first bottom electrode and the second bottom electrode are spaced apart from each other in a direction parallel to an upper surface of the substrate.

3. The display device of claim 2,
wherein the first contact hole and the second contact hole are spaced apart from each other with the channel region of the active layer and the gate electrode therebetween.

4. The display device of claim 3,
wherein a thickness of the active layer ranges from 50 angstroms to 500 angstroms.

5. The display device of claim 4,
wherein the active layer comprises an oxide semiconductor material.

6. The display device of claim 1, further comprising:
a buffer layer that entirely covers the first conductive layer,
wherein the first conductive layer and the active layer are spaced apart from each other with the buffer layer therebetween.

7. The display device of claim 1,
wherein the first bottom electrode and the second bottom electrode are configured to block light introduced into the active layer and stabilize electrical characteristics of the active layer.

8. A display device comprising:
a substrate;
a bottom electrode disposed on the substrate;
a subsidiary metal layer disposed on the substrate and comprising a first auxiliary metal and a second auxiliary metal, wherein the subsidiary metal layer is disposed higher than the bottom electrode relative to an upper surface of the substrate; and
a transistor disposed on the subsidiary metal layer,
wherein the transistor comprises:
an active layer comprising a source region, a channel region, and a drain region;
a gate electrode disposed on the channel region of the active layer; and
a source electrode and a drain electrode disposed on the gate electrode,
wherein a first vertical extension of the source electrode contacts the first auxiliary metal through a first contact hole penetrating the source region of the active layer, and
wherein the drain electrode contacts the second auxiliary metal through a second contact hole penetrating the drain region of the active layer.

9. The display device of claim 8,
wherein the first auxiliary metal overlaps the source region of the active layer, and the second auxiliary metal overlaps the drain region of the active layer.

10. The display device of claim 9,
wherein the first auxiliary metal and the second auxiliary metal are spaced apart from each other in a direction parallel to the upper surface of the substrate.

11. The display device of claim 10,
wherein a thickness of the bottom electrode ranges from 1,000 angstroms to 3,000 angstroms, and a thickness of the subsidiary metal layer is lower than or equal to the thickness of the bottom electrode.

12. The display device of claim 8, further comprising:
a first buffer layer that entirely covers the bottom electrode,
wherein the bottom electrode and the subsidiary metal layer are spaced apart from each other with the first buffer layer therebetween.

13. The display device of claim 12,
wherein a second vertical extension of the source electrode contacts the bottom electrode through a third contact hole penetrating the first buffer layer.

14. The display device of claim 13,
wherein the bottom electrode and the first auxiliary metal are connected with each other through the source electrode.

15. The display device of claim 9,
wherein the active layer contacts the first and second auxiliary metals.

16. The display device of claim 15,
wherein the first auxiliary metal contacts the source region of the active layer, and the second auxiliary metal contacts the drain region of the active layer.

17. The display device of claim 9, further comprising:
a second buffer layer that entirely covers the subsidiary metal layer, and the active layer and the subsidiary metal layer are spaced apart from each other in a direction perpendicular to the upper surface of the substrate with the second buffer layer therebetween.

18. An electronic device, comprising:
a display device; and
a power supply configured to provide power to the display device,
wherein the display device comprises:
a substrate;
a bottom electrode disposed on the substrate;
a subsidiary metal layer disposed on the substrate and comprising a first auxiliary metal and a second auxiliary metal, wherein the subsidiary metal layer is disposed higher than the bottom electrode relative to an upper surface of the substrate; and
a transistor disposed on the subsidiary metal layer,
wherein the transistor comprises:
an active layer comprising a source region, a channel region, and a drain region;
a gate electrode disposed on the channel region of the active layer; and
a source electrode and a drain electrode disposed on the gate electrode,
wherein a first vertical extension of the source electrode contacts the first auxiliary metal through a first contact hole penetrating the source region of the active layer, and
wherein the drain electrode contacts the second auxiliary metal through a second contact hole penetrating the drain region of the active layer.

19. The electronic device of claim 18,
wherein the first auxiliary metal overlaps the source region of the active layer, and the second auxiliary metal overlaps the drain region of the active layer.

20. The electronic device of claim 18, further comprising:
a first buffer layer that entirely covers the bottom electrode,
wherein the first auxiliary metal and the second auxiliary metal are spaced apart from each other in a direction parallel to the upper surface of the substrate,
wherein a thickness of the bottom electrode ranges from 1,000 angstroms to 3,000 angstroms, and a thickness of the subsidiary metal layer is lower than or equal to the thickness of the bottom electrode,
wherein the bottom electrode and the subsidiary metal layer are spaced apart from each other with the first buffer layer therebetween,
wherein a second vertical extension of the source electrode contacts the bottom electrode through a third contact hole penetrating the first buffer layer, and
wherein the bottom electrode and the first auxiliary metal are connected with each other through the source electrode.
